(19) United States
(12) Patent Application Publication
(10) Pub. No.: US 2021/0174689 A1
(43) Pub. Date: Jun. 10, 2021

(54) SITUATIONAL AWARENESS GROUND TRANSMITTER

(71) Applicant: BAE SYSTEMS Information and Electronic Systems Integration Inc., Nashua, NH (US)

(72) Inventor: Peter Ladubec, JR., Centereach, NY (US)

(73) Assignee: BAE SYSTEMS Information and Electronic Systems Integration Inc., Nashua, NH (US)

(21) Appl. No.: 16/703,121

(22) Filed: Dec. 4, 2019

(51) Int. Cl. G08G 5/00; G08G 5/02

(52) U.S. Cl. CPC G08G 5/0082; G08G 5/025; G08G 5/0026; G08G 5/0013; G08G 5/0078

(57) ABSTRACT

Techniques are disclosed that are designed to transmit low power radio frequency (RF) signals that include location parameters of one or more ground-based objects. Example systems include at least one or more processors and RF circuitry. The one or more processors are configured to generate one or more digital signals having a given number of bits. In one of the digital signals, a first portion of the bits includes location information for a ground-based object, a second portion of the bits includes heading information associated with the ground-based object, and a third portion of the bits includes speed information associated with the ground-based object. A second digital signal can include the size of the ground-based object. The RF circuitry converts the one or more digital signals into RF signals and transmits the RF signals at a given periodic pulse rate.

### FIELD OF THE DISCLOSURE

This disclosure relates generally to location tracking of ground-based objects, and more specifically, to transmission of location tracking data using an automatic dependent surveillance-broadcast (ADS-B) transponder.

### BACKGROUND

In a tactical military environment, stationary objects can be an obstacle for landing aircraft. Depending on the environment and type of landing aircraft, visibility may be diminished thus making the landing operation more difficult. This may especially be the case for helicopters that kick up dirt and sand as they are trying to land, thus potentially obscuring ground-based objects located around the landing zone, including potential risks to the aircraft or personnel. Challenges exist with providing reliable, fast, and safe information with regards to ground-based objects, particularly for aircraft landing.

### BRIEF DESCRIPTION OF THE DRAWINGS

FIG. 1 is an illustration of a typical landing zone that includes a number of ground-based obstacles.

FIG. 2 is an illustration of a ground transmitter sending RF signals to an aircraft, in accordance with an embodiment of the present disclosure.

FIG. 3 is a block diagram illustrating example transponder circuitry that may be used in the ground transmitter of FIG. 2, in accordance with an embodiment of the present disclosure.

FIG. 4 illustrates an example message format that may be transmitted using the transponder circuitry of FIG. 3, in accordance with an embodiment of the present disclosure.

FIG. 5 illustrates another example message format that may be transmitted using the transponder circuitry of FIG. 3, in accordance with an embodiment of the present disclosure.

FIGS. 6A and 6B illustrate example chip package designs for implementing a system-on-chip (SoC) for the transponder circuitry of FIG. 3, according to some embodiments of the present disclosure.

FIG. 7 is a flow diagram illustrating an example process for transmitting the location of one or more ground-based objects, in accordance with an embodiment of the present disclosure.

FIG. 8 is a block diagram illustrating selected components of ground transmitter comprising transponder circuitry, in accordance with an embodiment of the present disclosure.

These and other features of the present embodiments will be understood better by reading the following detailed description, taken together with the figures herein described.

### DETAILED DESCRIPTION

As mentioned above, there are a number of non-trivial issues associated with providing fast and reliable information about ground-based objects in a given region. The ability to quickly deploy aids to transmit locations of one or more obstacles in a tactical environment would greatly enhance situational awareness. Ideally, such aids should consume low power and fit into a small form factor for easy transportation and/or integration with other devices. Furthermore, the low power RF transmission output from the deployed aids is safer compared to high-power RF transmission as it does not have a long travel distance and thus is less susceptible to jamming or being intercepted by enemy transponders or otherwise used for airborne threats. Some embodiments of the present disclosure utilize the ADS-B functionality found in existing transponders on most aircraft. In particular, one or more ADS-B transponders are deployed at various locations on the ground at or otherwise adjacent to the landing site. The ADS-B transponders are configured with an interface to allow for position programming for one or more ground-based objects (e.g., vehicles, buildings, trees, large rock formations, etc) also proximate to the landing site. The ADS-B transponders are programmed or otherwise configured to “squitter” RF signals at a given periodic rate using a known standard modulation scheme (such as using Mode-S modulation). The ADS-B transponders are programmed or otherwise configured such that the squittered signals include various types of information regarding one or more ground-based objects, such as location information (e.g., longitude and latitude), heading information, speed, information, and size information, to name a few examples. Of course, fixed objects, such as a building, will have no heading per se and a speed of zero, which may be reflected in the data in the same way as done for a moving object.

Embodiments pertaining to the ADS-B transponders may be used in other applications in addition to identifying ground-based objects for a landing helicopter or other aircraft. For example, such transponders can provide the GPS coordinates of multiple tagged ground-based objects, such as military vehicles in a certain area, or wounded soldiers on the battlefield, or any other ground-based objects of interest.

In more detail, and in accordance with an embodiment, a system designed to transmit radio frequency (RF) signals includes at least one or more processors and RF circuitry. The one or more processors are configured to generate a coded digital signal having a given number of bits, wherein a first portion of the bits comprises location information for a ground-based object (e.g., GPS coordinates), a second portion of the bits comprises heading information associated with the ground-based object, and a third portion of the bits comprises speed information associated with the ground-based object. The RF circuitry converts the coded digital signal into an RF signal and transmits the RF signal at a given periodic pulse rate. The transmitted RF signal can then be received, for example, by an aircraft that includes a receiver configured to receive the transmitted RF signal, or a ground-based team or platform. Any number of such use cases or application will be appreciated in light of this disclosure.

In accordance with another embodiment, a system-on-chip package includes one or more processors implemented on a first die, RF circuitry implemented on a second die, and an interposer bonded to at least the first die and the second die. The one or more processors are configured to generate a coded digital signal having a given number of bits, wherein a first portion of the bits comprises location information (e.g., GPS coordinates, or other geolocation data) for a ground-based object, a second portion of the bits comprises heading information associated with the ground-based object, and a third portion of the bits comprises speed information associated with the ground-based object. The RF circuitry converts the coded digital signal into an RF signal and transmits the RF signal at a given periodic pulse rate.

In accordance with another embodiment, a method for transmitting the location of one or more ground-based objects includes generating, using one or more processors, a coded digital signal having a given number of bits, wherein a first portion of the bits comprises location information for the ground-based object, a second portion of the bits comprises heading information associated with the ground-based object, and a third portion of the bits comprises speed information associated with the ground-based object; converting the coded digital signal into an RF signal; and transmitting, using an RF transmitter, the RF signal.

The disclosed techniques greatly enhance situational awareness for a given area. For example, and according to an embodiment, the techniques provide a cost-effective means to provide accurate location data for one or more ground-based objects that may otherwise have been difficult to detect using sensors or the naked eye, any other object of interest. The ground-based objects may include man-made stationary objects (such as buildings, signal towers, power lines, etc.), naturally occurring objects (such as trees, rock formations, hills, etc.), moving objects (such as automobiles, military vehicles, taxiing aircraft, etc.), or even living things, (such as large animals or people). Moreover, the disclosed geolocation technique can be implemented in a relatively efficient manner by, for example, modifying existing identification friend-or-foe (IFF) interrogator systems or IFF transponder systems, and reusing or otherwise leveraging the hardware and components of such existing systems.

For example, in some such embodiments, the generation of an ADS-B signal that includes the geolocation data for one or more ground-based objects may be performed by processors and circuits of existing IFF interrogator systems or IFF transponder systems such that no additional sensor or electronics unit is required to generate and transmit such signals, making this a cost-effective solution. In such cases, firmware or software upgrades can be made to utilize the existing hardware and components of existing IFF systems as variously described herein. By way of an example, any number of non-transitory machine-readable mediums (e.g., embedded memory, on-chip memory, read only memory, random access memory, solid state drives, and any other physical storage mediums) can be used to encode the instructions that, when executed by one or more processors, cause the techniques provided herein to be carried out. These and other advantages and alternative embodiments will be apparent in light of this disclosure.

Example Tactical Environment

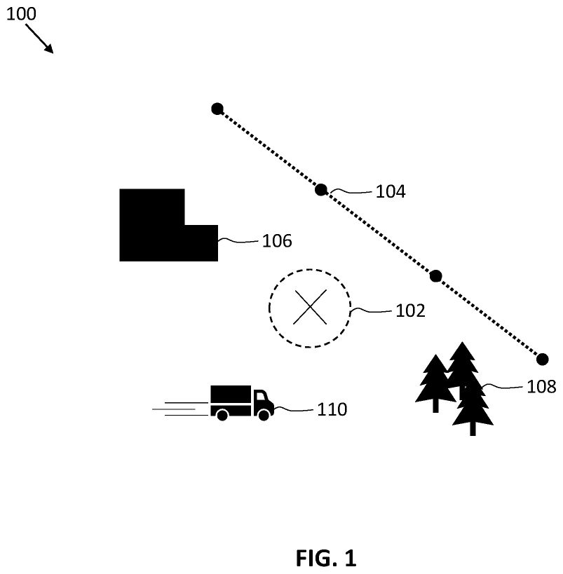

FIG. 1 illustrates an example environment 100 that includes a landing zone 102. Environment 100 may be any outdoors environment on land or on a sea vessel, such as an aircraft carrier. Landing zone 102 may be a dedicated landing zone, such as man-made landing zone structure, or it may represent an ad-hoc landing zone. Landing zone 102 may represent a relatively small area used as a landing area for aircraft such as helicopters or small drones. In some other embodiments, landing zone 102 represents a runway or larger area for landing larger aircraft, such as jets.

One or more ground-based objects exist in a given vicinity around landing zone 102. For example, power lines 104 may run close to landing zone 102. Power lines 104 may be difficult to see when landing near to them, especially in the case of helicopters which can kick up dirt and other debris as they land. Other examples of ground-based objects include building 106 and trees 108.

In some embodiments, the ground-based objects include moving objects such as vehicle 110. Vehicle 110 may be moving at any speed and along a path that brings vehicle 110 within a given distance of landing zone 102. In some embodiments, the movement path of vehicle 110 intersects with landing zone 102.

Due to the possible number of ground-based objects present at any given time, and the uncertainty about their locations in an ad-hoc environment, it can be difficult to safely land an airborne vehicle at landing zone 102. Accordingly, embodiments of systems and methods herein are provided that can transmit geolocation information about one or more of the ground-based objects to an incoming airborne vehicle. According to some embodiments, the transmissions are performed using ADS-B compliant transponders, such that Mode-S modulated messages can be sent that are very low power. The low power reduces the possibly that the messages are intercepted by enemy sensors, or that the messages are jammed. For example, the transmission power of the Mode-S modulated messages can have a signal level of less than 20 dBm, less than 30 dBm, less than 40 dBm, or less than 50 dBm.

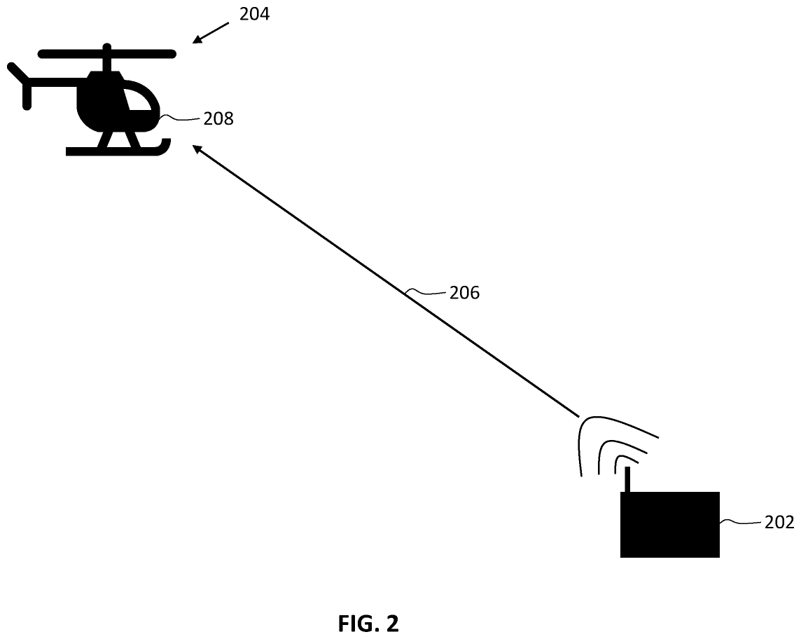

FIG. 2 illustrates a diagram of an example use case where a transponder system 202 transmits geolocation data 206 for one or more ground-based objects to an incoming aircraft 204. The geolocation data 206 is received by a complimentary transponder system 208 onboard, or at least associated with, incoming aircraft 204. Incoming aircraft 204 is illustrated as being a helicopter, but incoming aircraft 204 may by any airborne vehicle such as a fighter jet, a passenger jet, an unmanned vehicle, a rocket, a missile, etc. Transponder system 202 may be ground-based as a stand-alone system, or it may be physically attached to at least one ground-based object. In some examples, transponder system 202 is designed to provide the location of the ground-based object that it is attached to. In other examples, transponder system 202 is designed to provide the location of any number of surrounding ground-based objects. In some embodiments, transponder system 202 provides geolocation information for one or more adjacent ground-based objects. The surrounding objects can include friendly or non-friendly assets with transponder system 202 collecting data from other sensors or systems and relaying the data to aircraft 204.

According to some embodiments, both transponder system 202 and complimentary transponder system 208 are ADS-B compliant transponders that can send and/or receive various message formats including, for example, Selective Identification Feature (SIF), Mode S, Mode 4, and Mode 5. The transmitted geolocation data 206 can be encoded and modulated in multiple ways, such as minimum-shift keying (MSK) modulation (such as in pulses each having numerous bits encoded using MSK modulation) and digital signal modulation (e.g., pulses including rising and falling edges having corresponding rise and fall times), to provide two examples. For example, and in one embodiment, geolocation data 206 may be encoded for modulation as electromagnetic radiation, such as modulated at 1090 MHz waveforms when using a Mode-S downlink format DF-17. Other downlink formats may be used as well while maintaining a similar message format, such as DF-16, DF-18, DF-20, and DF-21. The parameters of the message sent in geolocation data 206 provide GPS coordinates and movement status of one or more ground-based objects, according to some embodiments. Geolocation data 206 can include more than one message where each of the messages contains some piece of information regarding the one or more ground-based objects.

According to some embodiments, transponder system 202 is designed to “squitter” the coded geolocation data 206 to incoming aircraft 204. As used herein, the term “squitter” means to transmit data pulses at a periodic rate. In one embodiment, transponder system 202 is designed to squitter geolocation data 206 containing one or messages regarding the locations of one or more ground-based objects at a pulse rate of every 3 seconds, every 5 seconds, or every 10 seconds for stationary objects. For moving objects, transponder system 202 may squitter geolocation data 206 containing one or messages regarding the locations of one or more of the moving ground-based objects at a pulse rate of every second, every 0.5 seconds, or every 0.1 seconds.

Transponder Architecture

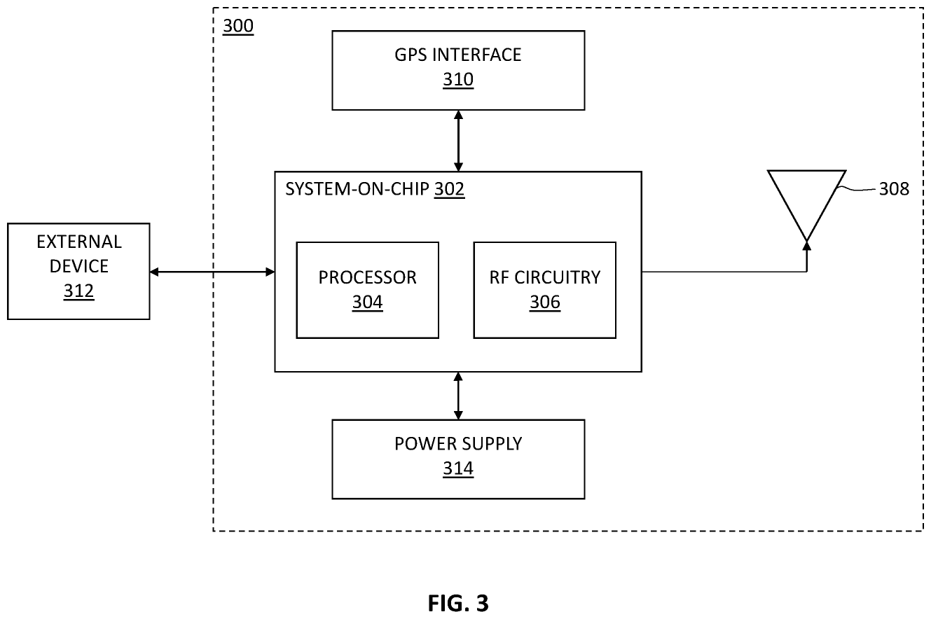

FIG. 3 is a block diagram of transponder circuitry 300 used within transponder system 202, according to an embodiment. Transponder circuitry 300 includes one or more processors 304 (herein referred to as processor 304) and RF circuitry 306. Processor 304 and RF circuitry 306 may be implemented as a system-on-chip (SoC) 302, and thus may be packaged together in a same chip package. In one example, processor 304 is implemented on a first die and RF circuitry 306 is implemented on a second die, and the two dies are incorporated together in the same chip package. In another example, processor 304 and RF circuitry 306 are implemented on the same die within the chip package. Transponder circuitry 300 may further include an antenna 308, a GPS interface 310, and a power supply 314. Processor 304, RF circuitry 306, and antenna 308 may be communicatively coupled to one or more of the other. In various embodiments, additional components or a subset of the illustrated components can be employed without deviating from the scope of the present disclosure. For instance, in various embodiments, transponder circuitry 300 may not include every one of the components illustrated in FIG. 3, but transponder circuitry 300 may connect or otherwise couple to the one or more components via interface circuitry. Other embodiments may integrate the various functionalities of the illustrated components into fewer components or more components. In a more general sense, the degree of integration and distribution of the functional component(s) provided herein can vary greatly from one embodiment to the next, and this disclosure should not be construed as limited in this regard.

Processor 304 can be any suitable processor, and may include one or more coprocessors or controllers, to assist in control and processing operations associated with transmitting geolocation data for one or more ground-based objects. In some embodiments, processor 304 may be implemented as any number of processor cores. The processor (or processor cores) may be any type of processor, such as, for example, a micro-processor, an embedded processor, a digital signal processor (DSP), a network processor, a field programmable gate array or other device configured to execute code. Processor 304 may include multithreaded cores in that it may include more than one hardware thread context (or “logical processor”) per core.

According to some embodiments, processor 304 is configured to encode a digital message that includes parameters associated with geolocation and/or movement of one or more ground-based objects. In some embodiments, each encoded message may be associated with a single corresponding ground-based object, and multiple encoded messages are squittered at a given pulse rate to be received by any incoming aircraft. All of the squittered encoded messages may be associated with a same ground-based object, or any number of different ground-based objects. The messages may include a given number of bits where various portions of the bits are dedicated to conveying particular information about the associated ground-based object. For example, a first portion of the bits includes location information for the ground-based object, a second portion of the bits includes heading information associated with the ground-based object, and a third portion of the bits includes speed information associated with the ground-based object. Additional information such as whether the ground-based object is a friend or foe or even whether the status is unknown can also be included. The type of asset can also be included such as building, power lines, human, animal, truck, etc., so that a risk profile can be considered. For example, if the asset identifies nearby power lines and the on-board sensors indicate very high winds, the asset can take appropriate action.

In one example, a Mode-S DF-17 squittered message includes 56 bits. Table 1 below provides one example of how the bits may be allocated in the 56-bit message.

TABLE 1
Surface Position Squitter Fields of DF17 Extended Squitter

| Number | | |
|---|---|---|
| of bits | Contents | Description |
| 5 | Format type code | Extended Squitter Type (plus flags) 5 |
| | | thru 8 |
| 7 | Movement | Ground Speed |
| 1 | Status | Validity Flag |
| 7 | Ground track | Direction of Movement (heading) |
| 1 | Time | UTC Time Flag |
| 1 | CPR format | Compact Position Reporting |
| 17 | CPR encoded latitude | Latitude |
| 17 | CPR encoded longitude | Longitude |

As can be observed in Table 1, 34 bits may be allocated to provide the geolocation (e.g., latitude and longitude) of a ground-based object while 7 bits may be allocated to provide the ground speed of the ground-based object, and another 7 bits may be allocated to provide the heading of the ground-based object. The bits may be allocated in any order, such that groups of bits pertaining to one type of information do not need to be located adjacent to one another.

The format type code may be included to determine the message format of the remaining bits in the message. For example, the format type code can differentiate messages into several classes, such as airborne position, airborne velocity, surface position, identification, aircraft status, etc. When using squittered messages associated with ground-based positions of various objects, the format type code may be used to designate the message class ‘surface position.’ As noted in Table 1, the ‘surface position’ message class may be designated by using any of codes 5 through 8.

### Messaging Format and Protocol

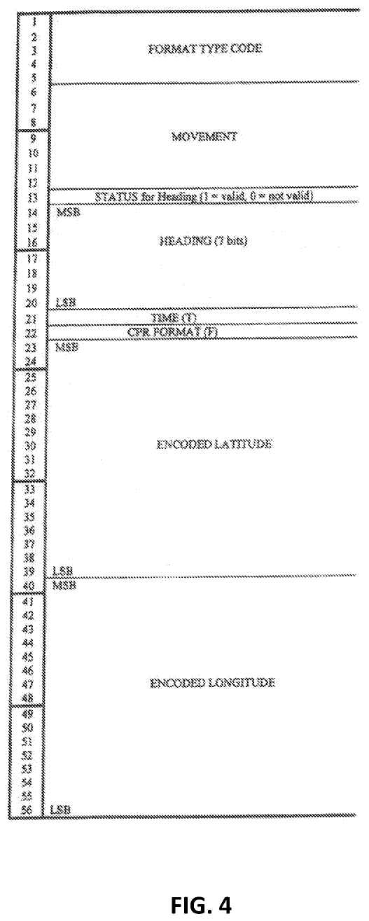

FIG. 4 illustrates one specific example of a Mode-S DF-17 data message that has the same bit allocation as that provided in Table 1. The various values for each set of bits may represent different conditions for the ground-based object. As seen from FIG. 4, any number of other bits may be used in the transmitted message for other purposes not directly related to providing location and/or movement information for the ground-based object.

In one example, bits 6-12 of the message shown in FIG. 4 have been allocated to designate the movement of the ground-based object. This allows for 128 different movement codes to represent the movement of the ground-based object. Table 2 below illustrates one example of how the 128 movement codes could be implemented.

TABLE 2
Movement codes for use in a Mode-S message

| Coding | Meaning | Quantization |
|---|---|---|
| 0 | No Movement Info Available | N/A |
| 1 | A/C Stopped (GS = 0 knots) | N/A |
| 2 | 0 knots < GS < 0.125 knots | N/A |
| 3-8 | 0.125 knots < GS <1.0 knot | 0.2700833 km/h |
| 9-12 | 1.0 knot < GS < 2.0 knots | 0.25 knot steps |
| 13-38 | 2 knots < GS < 15.0 knots | 0.50 knot steps |
| 39-93 | 15.0 knots < GS < 70.0 knots | 1.00 knot steps |
| 94-108 | 70.0 knots < GS < 100.0 knots | 2.00 knot steps |
| 109-123 | 100.0 knots < GS < 175.0 knots | 5.00 knot steps |
| 124 | 175 knots < GS | N/A |
| 125 | Reserved for A/C Decelerating | N/A |
| 126 | Reserved for A/C Accelerating | N/A |
| 127 | Reserved for A/C Backing Up | N/A |

Similarly, bits 14-20 of the message shown in FIG. 4 have been allocated to designate the heading of the ground-based object. This allows for 128 different heading codes to represent the heading of the ground-based object. Each of the heading codes can represent a direction in degrees clockwise from a reference point, such as true or magnetic north. In one example, each heading code from 0 to 127 represents a heading of (360/128) multiplied by the heading code. Using this example, a heading code of 18 represents of heading of (360/128)*18=50.625 degrees. In some embodiments, any number of bits may be used to designate the heading, with more bits providing finer resolution of the heading value.

According to some embodiments, the geolocation of a ground-based object is provided in the encoded message of FIG. 4 using latitude/longitude information from bits 23-56. Not all 34 bits may be required to provide latitude/longitude information, especially for stationary ground-based objects. The latitude/longitude information may be entered manually into a given transponder system 202 or may be uploaded into transponder system 202 from any external source. In some other examples, the latitude/longitude information may be determined using a coupled global positioning system (GPS) interface 310. The GPS interface 310 may be coupled to any part of transponder circuitry 300 and used to receive GPS coordinates from a satellite network (e.g., Navstar).

In some embodiments, a fourth group of bits in the message are used to represent a size of the ground-based object. Any of the other bits of the 56 bits used in the Mode-S message of FIG. 4 can be used to represent the size data. However, due to the limited number of bits in the message, a second message may be squittered that includes the size data of a ground-based object as another set of bits in the second message.

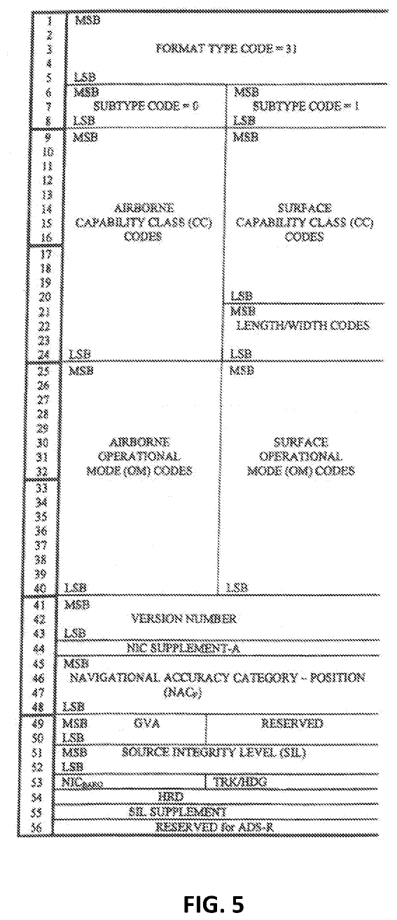

FIG. 5 illustrates another example of a Mode-S DF-17 data message that includes a portion of the bits (e.g., bits 21-24) that represent a size of the ground-based object, according to some embodiments. The data message of FIG. 5 also includes a different format type code (e.g., 31 in this example) to differentiate the message format from the message of FIG. 4. Furthermore, the subtype code used with bits 6-8 may be set to a value of ‘1’ (e.g., the three bits are set to 1-0-0) to indicate that the message is a surface status message as opposed to an airborne status message.

According to some embodiments, the sixteen codes provided by the four size bits are used to determine upper bounds of length and width for the ground-based object. Table 3 below provides one example of how the codes can be associated with the length and width of the ground-based object.

TABLE 3
Length/width codes for use in a Mode-S message

| | | | | | Upper-Bound Length and Width | |
|---|---|---|---|---|---|---|
| A/V - L/W | Length Code | | | Width Code | for Each Length/Width Code | |
| Code | “ME” | “ME” | “ME” | “ME” | Length | Width |
| (Decimal) | Bit 49 | Bit 50 | Bit 51 | Bit 52 | (meters) | (meters) |
| 0 | 0 | 0 | 0 | 0 | No Data or Unknown | |
| 1 | 0 | 0 | 0 | 1 | 15 | 23 |
| 2 | 0 | 0 | 1 | 0 | 25 | 28.5 |
| 3 | | | | 1 | | 34 |
| 4 | 0 | 1 | 0 | 0 | 35 | 33 |
| 5 | | | | 1 | | 38 |
| 6 | 0 | 1 | 1 | 0 | 45 | 39.5 |
| 7 | | | | 1 | | 45 |
| 8 | 1 | 0 | 0 | 0 | 55 | 45 |
| 9 | | | | 1 | | 52 |
| 10 | 1 | 0 | 1 | 0 | 65 | 59.5 |
| 11 | | | | 1 | | 67 |
| 12 | 1 | 1 | 0 | 0 | 75 | 72.5 |
| 13 | | | | 1 | | 80 |
| 14 | 1 | 1 | 1 | 0 | 85 | 80 |
| 15 | | | | 1 | | 90 |

Although length and width are discussed when encoding a size of the ground-based object, other size parameters may be used as well. For example, three dimensions (length, width, and height) may be used and encoded using either more bits or a different coding scheme for the existing 16 codes. In another example, size of the ground-based object may be represented by a volume that may be coded using any number of bits.

As noted above for the Mode-S message of FIG. 4, the Mode-S message of FIG. 5 may include any number of bits that are not used in the determination of the size of a ground-based object. These other bits can be used for any other communication or data processing purposes. For example, bits 9-20 designated as “surface capability class codes” may be used to report the operational capability of transponder system 202 while bits 25-40 designated as “surface operational mode codes” may be used to report the current operational mode of transponder system 202. In some embodiments, both Mode-S messages from FIG. 4 and FIG. 5 would be sent together as part of geolocation data 206.

RF circuitry 306 is configured to transmit signals, such as Mode-S messages, through antenna 308. Antenna 308 may be a rotating or stationary antenna. In some embodiments, antenna 308 represents an antenna array. In some embodiments, antenna 308 represents a microstrip antenna printed on a dielectric material disposed within SoC 302. The microstrip antenna may be printed on a same die that includes RF circuitry 306.

RF circuitry 306 may be configured to transmit modulated signals, such as radar signals, in a pre-established frequency band or channel, such as the L-band of the RF frequency spectrum (e.g., 500 MHz to 1500 MHz) and, in a specific embodiment, in the 1090 MHz channel. In some such embodiments, RF circuitry 306 includes RF components such as amplifiers, filters, and the like. In some embodiments, RF circuitry 306 is configured to transmit ADS-B Mode-S messages to be received by complementary transponder systems. For example, and according to an embodiment, RF circuitry 306 can receive encoded digital messages from processor 304, such as those illustrated in FIG. 4 or 5. In response, RF circuitry 306 can convert the digital signal to an analog signal (using, for example, a standard digital-to-analog (DAC) converter), modulate either the analog signal or the encoded digital message on a 1090 MHz carrier wave, amplify the modulated signals, and transmit the resulting message signals over antenna, 308. In some embodiments, the encoded message signals may be encrypted to prevent eavesdropping by unintended nearby recipients in certain applications where security may be a consideration.

As discussed previously, the squittered messages generated by processor 304 may be transmitted at a given pulse rate depending on whether the message is associated with a stationary ground-based object or a moving ground-based object. For example, messages associated with a stationary ground-based object can be transmitted at a pulse rate between every 3 seconds and every 7 seconds, such as every 5 seconds. In another example, messages associated with a moving ground-based object can be transmitted at a rate between every 0.2 seconds and every 0.7 seconds, such as every 0.5 seconds.

According to some embodiments, transponder circuitry 300 includes a power supply 314 to provide the power needed to operate any or all of the other components of transponder circuitry 300. Power supply 314 may include one or more rechargeable batteries that may be recharged using a plug interface for receiving power from an external AC power source. In some other examples, power supply 314 includes one or more rechargeable batteries that are charged using solar cells arranged in a solar panel array. In some other examples, power supply 314 includes one or more rechargeable batteries that are charged using other energy harvesting methods, such as harvesting vibrational energy or wind energy. Power supply 314 may be designed to provide DC power to any or all of the other components of transponder circuitry 300.

According to some embodiments, data related to position, movement, or size of one or more ground-based objects may be received by processor 304 from an external device 312. Accordingly, transponder circuitry 300 may include receiver circuitry (not illustrated) to receive data from external device 312 and pass the data on to processor 304. Processor 304 may then use the received data to encode the Mode-S messages to be transmitted out to incoming aircraft. In some embodiments, the parameter data received from external device 312 is used to update the parameters of preexisting digital messages associated with one or more ground-based objects.

External device 312 may be a mobile device such as, for example, a laptop, smartphone, personal digital assistant (PDA), tablet, or smartwatch. The mobile device may include an app installed on the device that allows for transferring data between the mobile device and transponder circuitry 300. The transferred data includes parameters associated with one or more ground-based objects, such as the location, bearing, speed, and size of the one or more ground-based objects. For example, a user may manually enter parameters for a variety of ground-based objects around the user into a tablet held by the user. These parameters may then be transferred to transponder circuitry 300 within a given transponder system 202 and received by processor 304. Processor 304 in turn may encode such parameters into ADS-B messages with a Mode-S format that are transmitted out using RF circuitry 306 and antenna 308. The mobile device may communicate with transponder circuitry using any known communication technique. Example communication techniques include both wired and wireless interfaces, such as a serial interface (e.g., RS-232 or USB), a parallel interface, cellular signals, Bluetooth signals, WiFi signals, or optical (e.g., infrared) signals.

In some other embodiments, external device 312 is a personal computer (PC) or server that may be any distance away from transponder circuitry 300. In such examples, the PC or server may transfer data to transponder circuitry 300 via satellite or via cellular signals using a cell tower within range of transponder circuitry 300. Any other long-range signaling techniques may be used as well.

In some embodiments, external device 312 represents a computer onboard a vehicle. In such examples, a GPS interface linked with the onboard vehicle computer can provide geolocation information for the vehicle and this information can be transferred by the onboard vehicle computer to transponder circuitry 300. The transfer of data may be executed using any of the communication techniques discussed above.

In some embodiments, a given transponder system 202 that includes transponder circuitry 300 is physically coupled to a particular ground-based object and uses its own location to provide the location of the coupled ground-based object. For example, if transponder system 202 is coupled to a portion of a ground-based vehicle, it can use its own GPS coordinates to provide the location, speed, and heading of the ground-based vehicle. In some embodiments, parameters such as speed and heading may be provided using other sensors such as accelerometers or gyroscopes. Parameters associated with the size of the ground-based object may be entered into the given transponder system manually or may be received from external device 312.

System on Chip

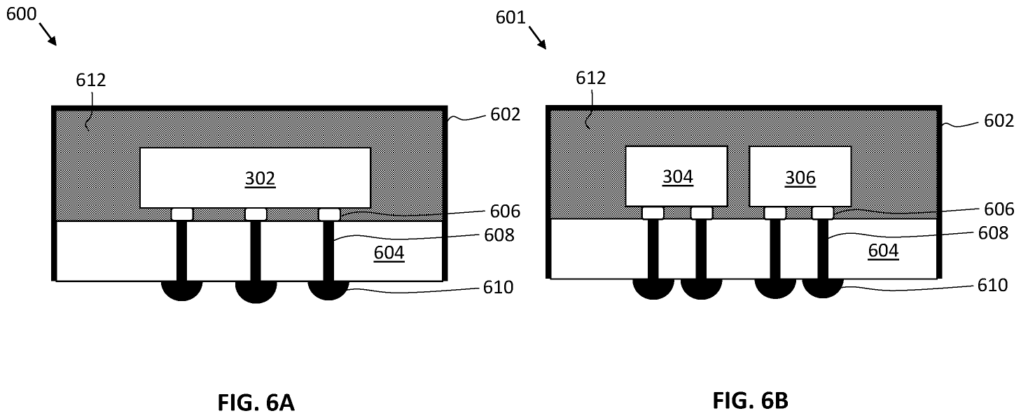

FIG. 6A illustrates an example embodiment of a SoC chip package 600. As can be seen, SoC chip package 600 may include SoC 302. SoC 302 may be a single die that includes both processor 304 and RF circuitry 306. In some embodiments, antenna 308 is printed on a portion of SoC 302. Other dies may be included as well within SoC chip package 600 and coupled to the same interposer 604. As can be further seen, SoC chip package 600 includes a housing 602 that is bonded to interposer 604. Housing 602 may be any material that provides environmental protection for the components of SoC chip package 600. SoC 302 may be conductively coupled to interposer 604 using connections 606. In some embodiments, connections 606 represent any standard or proprietary connection mechanism, such as solder bumps, ball grid array (BGA), pins, or wire bonds, to name a few examples. Interposer 604 may include a dielectric material having conductive pathways (e.g., including conductive vias and lines) extending through the dielectric material between the faces of interposer 604, or between different locations on each face. For example, interposer 604 may include multiple stacked layers of dielectric material with conductive traces running surfaces of one or more of the layers of dielectric material, and one or more conductive vias extending between any number of the layers of dielectric material. In some embodiments, interposer 604 may have a thickness less than 1 millimeter (e.g., between 0.1 millimeters and 0.5 millimeters), although any number of package geometries can be used. Additional conductive contacts 610 may be disposed at an opposite face of interposer 604 for conductively contacting, for instance, a printed circuit board or another chip package. One or more vias 608 extend through a thickness of interposer 604 to provide conductive pathways between one or more of connections 606 to one or more of contacts 610. Vias 608 may be single straight columns (as illustrated), however, other configurations can be used (e.g., damascene, dual damascene, through-silicon via). In still other embodiments, vias 608 are fabricated by multiple smaller stacked vias, or are staggered at different locations across various ones of the stacked dielectric layers of interposer 604. Contacts 610 may be solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 610, to inhibit shorting.

In some embodiments, a mold material 612 may be disposed around SoC 302 included within housing 602. In some embodiments, mold material 612 is included between SoC 302 and interposer 604 as an underfill material, as well as between SoC 302 and housing 602 as an overfill material. The dimensions and qualities of mold material 612 can vary depending on the type of chip package used and the environment the package is used in. In some embodiments, a thickness of mold material 612 is less than 1 millimeter. Example materials that may be used for mold material 612 include epoxy mold materials. In some cases, mold material 612 is thermally conductive, in addition to being electrically insulating. In some embodiments mold material 612 causes little to no attenuation of RF signals being received by, or transmitted from, SoC 302.

FIG. 5B illustrates another embodiment of a SoC chip package 601. SoC chip package 601 is also a system-on-chip that includes separate dies for processor 304 and RF circuitry 306 bonded to interposer 604. According to some embodiments, each of the separate dies are bonded to interposer 604 using connections 606. The remaining components of SoC chip package 601 may be the same as those described for SoC chip package 600. The separate dies used for processor 304 and RF circuitry 306 can be the same material or different materials.

Methodology

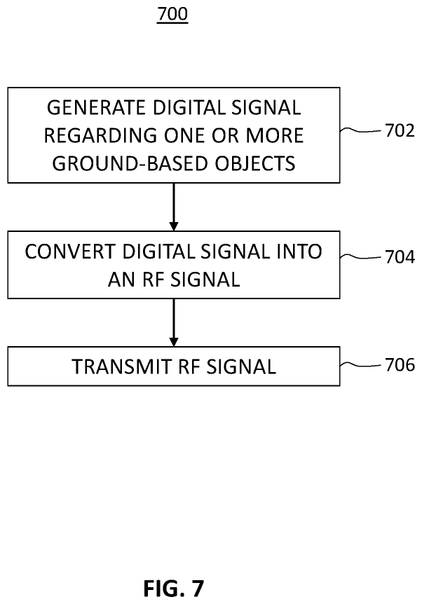

FIG. 7 is a flow diagram illustrating an example method 700 for transmitting the location of one or more ground-based objects, in accordance with some embodiments of the present disclosure. The operations, functions, or actions illustrated in example method 700 may in some embodiments be performed by transponder system 202. The operations, functions, or actions described in the respective blocks of example method 700 may also be stored as computer-executable instructions in a non-transitory computer-readable medium, such as a memory and/or a data storage of a computing system. In some instances, method 700 may be performed by components as part of a system-on-chip (SoC).

As will be further appreciated in light of this disclosure, for this and other processes and methods disclosed herein, the functions performed in method 700 may be implemented in differing order. Additionally or alternatively, two or more operations may be performed at the same time or otherwise in an overlapping contemporaneous fashion. Furthermore, the outlined actions and operations are only provided as examples, and some of the actions and operations may be optional, combined into fewer actions and operations, or expanded into additional actions and operations without detracting from the essence of the disclosed embodiments. To this end, each of the example processes depicted is provided to give one example embodiment and is not intended to limit the process to any particular physical or structural configuration.

With reference to example process 700, at operation 702, a digital signal is generated that includes information about one or more ground-based objects. The information includes parameters regarding the one or more ground-based objects, such as location, heading, speed, and/or size of the one or more ground-based objects. A single digital signal may be coded using a Mode-S modulation scheme to provide information about a single ground-based object. Multiple digital signals may be generated to provide information about a single ground-based object or to provide information about a plurality of ground-based objects.

According to some embodiments, one or more of the generated digital signals includes a certain number of bits, with portions of the bits allocated for particular parameters regarding the ground-based objects. For example, a single digital signal message may include 56 total bits where a first portion of the bits includes location information for the ground-based object, a second portion of the bits includes heading information associated with the ground-based object, and a third portion of the bits includes speed information associated with the ground-based object. The same digital signal message may also include a fourth portion of the bits that includes size information. In another embodiment, a separate digital signal is generated that includes a portion of bits allocated for size information about the ground-based object. The generated digital signals may be messages having a Mode-S format. Examples of digital signal messages generated using the Mode-S format are provided in FIGS. 4 and 5.

At operation 704, the digital signal is converted into an RF signal. The conversion may be performed using a standard DAC. In one embodiment, the digital signal is modulated onto an RF carrier wave. In another embodiment, the digital signal is converted to an RF signal and the RF signal is then modulated onto an RF carrier wave. The RF carrier wave may have a frequency of 1090 MHz. In some embodiments, the RF signal is amplified before being transmitted.

At operation 706, the RF signal having the modulated Mode-S message with data regarding one or more ground-based objects is transmitted via one or more antennas, according to some embodiments. The RF signal may be transmitted as an ADS-B signal to be received by a complementary transponder or interrogator onboard, for example, an aircraft. The transponder that receives the RF signal can demodulate the received signal to access the Mode-S message with information about the location, bearing, speed, and/or size of one or more ground-based objects.

System Architecture

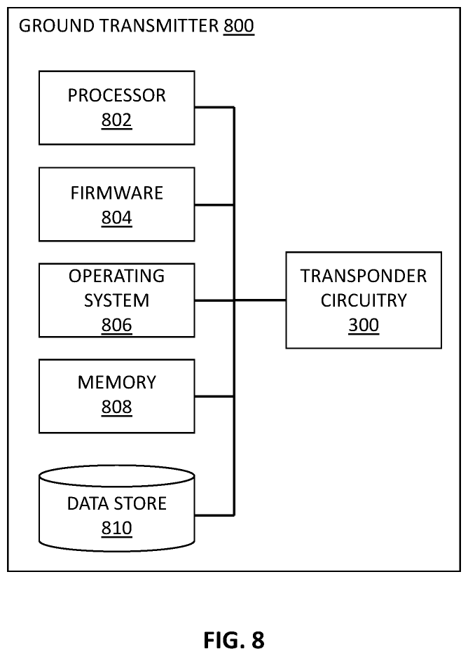

FIG. 8 is a block diagram illustrating selected components of an example ground transmitter 800 (such as transponder system 202) comprising transponder circuitry 300 and selected supporting components, in accordance with an embodiment of the present disclosure. As shown in FIG. 8, ground transmitter 800 includes a processor 802, a firmware 804, an operating system (OS) 806, a memory 808, a data store 810, and transponder circuitry 300. In various embodiments, additional components (not illustrated, such as a display, communication interface, input/output interface, etc.) or a subset of the illustrated components can be employed without deviating from the scope of the present disclosure. As noted above, ground transmitter 800 may be a standalone device that transmits ADS-B signals having messages with a Mode-S format regarding parameters associated with one or more surrounding ground-based objects. In some other embodiments, ground transmitter 800 is coupled to a moving or stationary ground-based object and transmits parameters associated with the coupled ground-based object.

Processor 802 can be any suitable processor, and may include one or more coprocessors or controllers, such as an audio processor, a graphics processing unit, or hardware accelerator, to assist in control and processing operations associated with ground transmitter 800. In some embodiments, processor 802 may be implemented as any number of processor cores. The processor (or processor cores) may be any type of processor, such as, for example, a micro-processor, an embedded processor, a digital signal processor (DSP), a graphics processor (GPU), a network processor, a field programmable gate array or other device configured to execute code. The processors may be multithreaded cores in that they may include more than one hardware thread context (or “logical processor”) per core. Processor 802 may be implemented as a complex instruction set computer (CISC) or a reduced instruction set computer (RISC) processor.

Memory 808 can be implemented using any suitable type of digital storage including, for example, flash memory and/or random access memory (RAM). In some embodiments, memory 808 may include various layers of memory hierarchy and/or memory caches as are known to those of skill in the art. Memory 808 may be implemented as a volatile memory device such as, but not limited to, a RAM, dynamic RAM (DRAM), or static RAM (SRAM) device. Data store 810 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, and/or a battery backed-up synchronous DRAM (SDRAM). In some embodiments, data store 810 may comprise technology to increase the storage performance enhanced protection for valuable digital media when multiple hard drives are included.

Processor 802 may be configured to execute OS 806 which may comprise any suitable operating system, such as Google Android (Google Inc., Mountain View, Calif.), Microsoft Windows (Microsoft Corp., Redmond, Wash.), Apple OS X (Apple Inc., Cupertino, Calif.), Linux, or a real-time operating system (RTOS). As will be appreciated in light of this disclosure, the techniques provided herein can be implemented without regard to the particular operating system provided in conjunction with ground transmitter 800, and therefore may also be implemented using any suitable existing or subsequently-developed platform. Processor 802 may be configured to execute firmware 804.

It will be appreciated that in some embodiments, the various components of ground transmitter 800 may be combined or integrated in a system-on-a-chip (SoC) architecture. In some embodiments, the components may be hardware components, firmware components, software components or any suitable combination of hardware, firmware or software.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

### FURTHER EXAMPLE EMBODIMENTS

The following examples pertain to further embodiments, from which numerous permutations and configurations will be apparent.

Example 1 is a system configured to transmit radio frequency (RF) signals. The system comprises one or more processors configured to generate a digital signal having a given number of bits, wherein a first portion of the bits comprises location information for a ground-based object, a second portion of the bits comprises heading information associated with the ground-based object, and a third portion of the bits comprises speed information associated with the ground-based object. The system also comprises RF circuitry configured to convert the digital signal into an RF signal, and to transmit the RF signal at a given periodic pulse rate.

Example 2 includes the subject matter of Example 1, wherein the one or more processors and the RF circuitry are provided in a same chip package as a system-on-chip (SoC).

Example 3 includes the subject matter of Example 1 or Example 2, wherein the first portion of the bits comprises a first sub-portion of bits associated with latitude of the ground-based object, and a second sub-portion of bits associated with longitude of the ground-based object.

Example 4 includes the subject matter of any one of Examples 1-3, further comprising a communication interface configured to receive parameters from an external device, wherein the one or more processors is configured to use the parameters to update any number of the given number of bits of the digital signal.

Example 5 includes the subject matter of any one of Examples 1-4, further comprising a rechargeable power supply.

Example 6 includes the subject matter of Example 5, further comprising a plurality of solar cells configured to charge the rechargeable power supply.

Example 7 includes the subject matter of any one of Examples 1-6, wherein the RF signal is transmitted out as an Automatic Dependent Surveillance-Broadcast (ADS-B) signal with Mode-S modulation.

Example 8 includes the subject matter of any one of Examples 1-7, wherein the one or more processors are further configured to generate a second digital signal having a given number of bits, wherein a portion of the bits of the second digital signal comprises information associated with a size of the ground-based object.

Example 9 includes the subject matter of any one of Examples 1-8, wherein the transmitted RF signal has a signal level of less than 30 dBm.

Example 10 includes the subject matter of any one of Examples 1-9, wherein the system is adjacent or attached to the ground-based object.

Example 11 is a system-on-chip (SoC) package that includes one or more processors implemented on a first die, and configured to generate a digital signal having a given number of bits, wherein a first portion of the bits comprises location information for a ground-based object, a second portion of the bits comprises heading information associated with the ground-based object, and a third portion of the bits comprises speed information associated with the ground-based object. The SoC package also includes RF circuitry implemented on a second die, and configured to convert the digital signal into an RF signal, and to transmit the RF signal at a given periodic pulse rate. The SoC package also includes an interposer bonded to at least the first die and the second die.

Example 12 includes the subject matter of Example 11, wherein the first portion of the bits comprises a first sub-portion of bits associated with latitude of the ground-based object, and a second sub-portion of bits associated with longitude of the ground-based object.

Example 13 includes the subject matter of Example 11 or Example 12, further comprising a communication interface configured to receive parameters from an external device, wherein the one or more processors is configured to use the parameters to update any number of the given number of bits of the digital signal.

Example 14 includes the subject matter of any one of Examples 11-13, further comprising a rechargeable power supply.

Example 15 includes the subject matter of Example 14, further comprising a plurality of solar cells configured to charge the rechargeable power supply.

Example 16 includes the subject matter of any one of Examples 11-15, wherein the RF signal is transmitted out as an Automatic Dependent Surveillance-Broadcast (ADS-B) signal with Mode-S modulation.

Example 17 includes the subject matter of any one of Examples 11-16, wherein the one or more processors are further configured to generate a second digital signal having a given number of bits, wherein a portion of the bits of the second digital signal comprises information associated with a size of the ground-based object.

Example 18 includes the subject matter of any one of Examples 11-17, wherein the transmitted RF signal has a signal level of less than 30 dBm.

Example 19 includes the subject matter of any one of Examples 11-18, wherein the SoC package is adjacent or attached to the ground-based object.

Example 20 is a method for transmitting the location of one or more ground-based objects, the method comprising: generating, using one or more processors, a digital signal having a given number of bits, wherein a first portion of the bits comprises location information for the one or more ground-based objects, a second portion of the bits comprises heading information associated with the one or more ground-based objects, and a third portion of the bits comprises speed information associated with the one or more ground-based objects; converting the digital signal into an RF signal; and transmitting, using an RF transmitter, the RF signal.

Example 21 includes the subject matter of Example 20, wherein the first portion of the bits comprises a first sub-portion of bits associated with latitude of the one or more ground-based objects, and a second sub-portion of bits associated with longitude of the one or more ground-based objects.

Example 22 includes the subject matter of Example 20 or Example 21, further comprising receiving, via a communication interface, parameters from an external device, wherein the generating comprises using the parameters to update any number of the given number of bits of the digital signal.

Example 23 includes the subject matter of any one of Examples 20-22, further comprising generating, using the one or more processors, a second digital signal having a given number of bits, wherein a portion of the bits of the second digital signal comprises information associated with a size of the one or more ground-based objects.

Example 24 includes the subject matter of any one of Examples 20-23, wherein the generating comprises generating a Mode-S digital signal.

Example 25 includes the subject matter of any one of Examples 20-24, wherein the transmitting comprises transmitting the RF signal with a signal level of less than 30 dBm.

As used in the present disclosure, the terms “circuit” or “engine” or “module” or “component” may refer to specific hardware implementations configured to perform the actions of the engine or module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations, firmware implements, or any combination thereof are also possible and contemplated. In this description, a “computing entity” may be any computing system as previously described in the present disclosure, or any module or combination of modulates executing on a computing system.

Terms used in the present disclosure and in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

All examples and conditional language recited in the present disclosure are intended for pedagogical examples to aid the reader in understanding the present disclosure, and are to be construed as being without limitation to such specifically recited examples and conditions. Although example embodiments of the present disclosure have been described in detail, various changes, substitutions, and alterations could be made hereto without departing from the spirit and scope of the present disclosure. Accordingly, it is intended that the scope of the present disclosure be limited not by this detailed description, but rather by the claims appended hereto.

What is claimed is:

1. A system configured to transmit radio frequency (RF) signals, comprising:
one or more processors configured to generate a digital signal having a given number of bits, wherein a first portion of the bits comprises location information for a ground-based object, a second portion of the bits comprises heading information associated with the ground-based object, and a third portion of the bits comprises speed information associated with the ground-based object; and
RF circuitry configured to convert the digital signal into an RF signal, and to transmit the RF signal at a given periodic pulse rate.

2. The system of claim 1, wherein the one or more processors and the RF circuitry are provided in a same chip package as a system-on-chip (SoC).

3. The system of claim 1, wherein the first portion of the bits comprises
a first sub-portion of bits associated with latitude of the ground-based object, and
a second sub-portion of bits associated with longitude of the ground-based object.

4. The system of claim 1, further comprising a communication interface configured to receive parameters from an external device, wherein the one or more processors is configured to use the parameters to update any number of the given number of bits of the digital signal.

5. The system of claim 1, wherein the system is adjacent or attached to the ground-based object.

6. The system of claim 1, wherein the RF signal is transmitted out as an Automatic Dependent Surveillance-Broadcast (ADS-B) signal with Mode-S modulation.

7. The system of claim 1, wherein the one or more processors are further configured to generate a second digital signal having a given number of bits, wherein a portion of the bits of the second digital signal comprises information associated with a size of the ground-based object.

8. The system of claim 1, wherein the transmitted RF signal has a signal level of less than 30 dBm.

9. A system-on-chip (SoC) package, comprising:
one or more processors implemented on a first die, and configured to generate a digital signal having a given number of bits, wherein a first portion of the bits comprises location information for a ground-based object, a second portion of the bits comprises heading information associated with the ground-based object, and a third portion of the bits comprises speed information associated with the ground-based object;
RF circuitry implemented on a second die, and configured to convert the digital signal into an RF signal, and to transmit the RF signal at a given periodic pulse rate; and
an interposer bonded to at least the first die and the second die.

10. The SoC package of claim 9, wherein the first portion of the bits comprises
a first sub-portion of bits associated with latitude of the ground-based object, and
a second sub-portion of bits associated with longitude of the ground-based object.

11. The SoC package of claim 9, further comprising a communication interface configured to receive parameters from an external device, wherein the one or more processors is configured to use the parameters to update any number of the given number of bits of the digital signal.

12. The SoC package of claim 9, wherein the SoC package is adjacent or attached to the ground-based object.

13. The SoC package of claim 9, wherein the RF signal is transmitted out as an Automatic Dependent Surveillance-Broadcast (ADS-B) signal with Mode-S modulation.

14. The SoC package of claim 9, wherein the one or more processors are further configured to generate a second digital signal having a given number of bits, wherein a portion of the bits of the second digital signal comprises information associated with a size of the ground-based object.

15. The SoC package of claim 9, wherein the transmitted RF signal has a signal level of less than 30 dBm.

16. A method for transmitting the location of one or more ground-based objects, the method comprising:
generating, using one or more processors, a digital signal having a given number of bits, wherein a first portion of the bits comprises location information for the one or more ground-based objects, a second portion of the bits comprises heading information associated with the one or more ground-based objects, and a third portion of the bits comprises speed information associated with the one or more ground-based objects;
converting the digital signal into an RF signal; and
transmitting, using an RF transmitter, the RF signal.

17. The method of claim 16, wherein the first portion of the bits comprises
a first sub-portion of bits associated with latitude of the one or more ground-based objects, and
a second sub-portion of bits associated with longitude of the one or more ground-based objects.

18. The method of claim 16, further comprising receiving, via a communication interface, parameters from an external device, wherein the generating comprises using the parameters to update any number of the given number of bits of the digital signal.

19. The method of claim 16, further comprising generating, using the one or more processors, a second digital signal having a given number of bits, wherein a portion of the bits of the second digital signal comprises information associated with a size of the one or more ground-based objects.

20. The method of claim 16, wherein the transmitting comprises transmitting the RF signal with a signal level of less than 30 dBm.
